(19) United States
(12) Patent Application Publication
(10) Pub. No.: US 2005/0135145 A1
(43) Pub. Date: Jun. 23, 2005

(54) Synchronous flash memory device and method of operating the same

(76) Inventors: You-Sang Lee, Gyeonggi-do (KR); Jin-Yub Lee, Seoul (KR)

Correspondence Address: MARGER JOHNSON & MCCOLLOM, P.C., 1030 SW MORRISON STREET, PORTLAND, OR, 97205, US

(21) Appl. No.: 10/957,382

(22) Filed: Sep. 30, 2004

(30) Foreign Application Priority Data
Dec. 22, 2003 (KR) 2003-94417

(51) Int. Cl. G11C 11/00

(52) U.S. Cl. 365/154

(57) ABSTRACT

A flash memory device includes a flash memory cell array, and an interface circuit, which receives a command and addresses sequentially in synchronization to an external system clock after a predetermined first latency is elapsed from when a chip enable signal is activated, in a read operation, in a program operation, and in an erase operation. The interface circuit receives the command in response to activation of an invoke signal. Therefore, since the flash memory device does not require CLE (Command Latch Enable) signals, ALE (Address Latch Enable) signals, RE (Read Enable) signals and WE (Write Enable) signals, internal circuits of the flash memory device can be simply controlled, thereby reducing a probability of skew generation in chips, improving performance, and decreasing the number of required pins.

### BACKGROUND OF THE INVENTION

This application claims the priority of Korean Patent Application No. 2003-94417, filed on Dec. 22, 2003, in the Korean Intellectual Property Office, the disclosure of which is incorporated herein in its entirety by reference.

1. Field of the Invention

This disclosure relates to a flash memory device, and more particularly, to a synchronous flash memory device that receives commands, addresses, and data in synchronization to an external system clock.

2. Description of the Related Art

Along with development of various application systems such as mobile systems, a flash memory device as a non-volatile memory device and a memory system for controlling the same have been in high demand.

A conventional NAND type flash memory device toggles a CLE (Command Latch Enable) signal and an ALE (Address Latch Enable) signal with a WE (Write Enable) signal to perform a write operation, and toggles the CLE signal and the ALE signal with a RE (Read Enable) signal to perform a read operation.

Such a conventional NAND type flash memory device operates in an asynchronous mode without being synchronized with an external system clock. In more detail, the conventional NAND type flash memory device operates in a defective synchronous mode in a manner to be synchronized with an internal signal without being synchronized with an external system clock, which requires many control signals. Accordingly, internal circuits of the conventional NAND type flash memory device are inevitably controlled in a complicated manner, which increases a probability of skew generation in chips, and requires many pins.

### SUMMARY OF THE INVENTION

Embodiments of the invention provide a flash memory device which reduces a probability of skew generation in chips, improves system performance and minimizes required pins.

Embodiments also provide a memory system including the flash memory device.

Embodiments of the invention also provide methods of operating, reading data from, and programming data into the flash memory device.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram schematically showing a flash memory device according to embodiments of the invention;

FIG. 2 is a block diagram schematically showing a memory system including the flash memory device of FIG. 1 according to embodiments of the invention;

FIG. 3 is a timing chart illustrating an example read operation of the flash memory device of FIG. 1;

FIG. 4 is a timing chart illustrating an example program operation of the flash memory device of FIG. 1;

FIG. 5 is a timing chart illustrating an example erase operation of the flash memory device of FIG. 1; and

FIG. 6 is a timing chart illustrating an example cache program operation of the flash memory device of FIG. 1.

### DETAILED DESCRIPTION OF THE INVENTION

Hereinafter, embodiments of the present invention will be described in detail with reference to the appended drawings. The same reference numbers refer to the same components throughout the drawings.

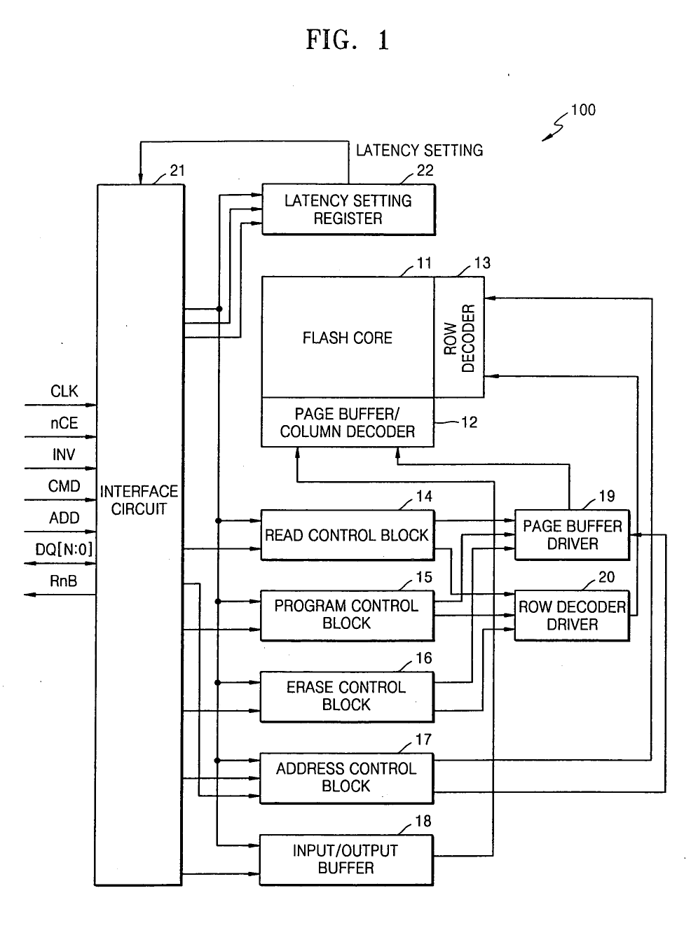

FIG. 1 is a block diagram schematically showing a flash memory device according to the present invention.

Referring to FIG. 1, a flash memory device 100 according to embodiments of the invention includes a flash core 11, a page buffer/column decoder 12, a row decoder 13, a read control block 14, a program control block 15, an erase control block 16, an address control block 17, an input/output buffer 18, a page buffer driver 19, a row decoder driver 20, an interface circuit 21, and a latency setting register 22.

The flash core 11 includes a flash memory cell array. The page buffer/column decoder 12, the row decoder 13, the control blocks 14, 15, 16 and 17, the input/output buffer 18, the page buffer driver 19, and the row decoder driver 20 are generally included in a flash memory device, and therefore detailed descriptions thereof are omitted.

The latency setting register 22 stores latency values and provides the stored latency values to the interface circuit 21. Especially, the interface circuit 21 has a scheme which sequentially receives a command CMD and addresses ADDs in synchronization to an external system clock CLK after a predetermined latency is elapsed from when a chip enable signal nCE received from an external source is activated, in a read operation, in a program operation, and in an erase operation. Here, the command CMD is received in response to an invoke signal INV.

That is, the conventional flash memory device receives the command CMD in response to a command latch enable (CLE) signal and receives the addresses ADDs in response to an address latch enable (ALE) signal, without being synchronized to the external system clock CLK. However, the flash memory device 100 of FIG. 1 can receive the command CMD and the addresses ADDs in synchronization to the external system clock CLK without any CLE signal or any ALE signal, in all of the read operation, the program operation, and the erase operation.

Also, in a read operation, the interface circuit 21 receives a command CMD and addresses ADDs, and outputs read data sequentially through an input/output (DQ) pin into an external source, in synchronization to the external system clock CLK after a predetermined second latency is elapsed from when a confirm command is received. In a program operation, the interface circuit 21 receives a command CMD and addresses ADDs, and receives program data sequentially through the input/output (DQ) pin in synchronization to the external system clock CLK after a predetermined third latency is elapsed from when a confirm command is received.

That is, the conventional flash memory device outputs read data to an external source through an input/output (DQ) pin in response to an RE (Read Enable) signal, and receives program data through the input/output (DQ) pin in response to a WE (Write Enable) signal. However, the flash memory device 100 of FIG. 1 can output read data to an external source through the input/output (DQ) pin in synchronization to an external system clock CLK without the RE signal, and can receive the program data through the input/output (DQ) pin in synchronization to the external system clock CLK without the WE signal.

Therefore, since the flash memory device 100 does not require CLE signals, ALE signals, RE signals and WE signals, accordingly, the internal circuits of the flash memory device 100 can be simply controlled, thereby reducing the probability of skew generation in chips, improving performance, and decreasing the number of required pins.

In the flash memory device 100, example sizes of program data and read data are set based on a 512-byte (+16 bytes) sector size. Accordingly, the flash memory device 100 is FAT (File Allocation Table)—compatible with a different mass memory system based on a 512-byte sector size, such as a hard-disk. Also, the flash memory device 100 can support program data and read data up to 2K bytes based on the 512-byte size.

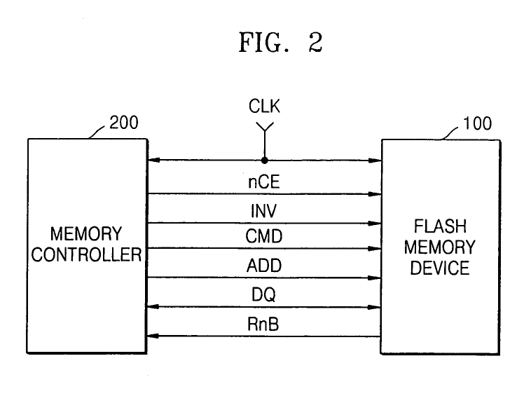

FIG. 2 is a block diagram schematically showing a memory system including the flash memory device of FIG. 1 according to embodiments of the invention.

Referring to FIG. 2, the flash memory device 100 is connected to a memory controller 200. The memory controller 200 generates a chip enable signal nCE, an invoke signal INV, a command CMD, and addresses ADDs, and provides the generated data to the flash memory device 100. The invoke signal INV may be generated in the flash memory device 100.

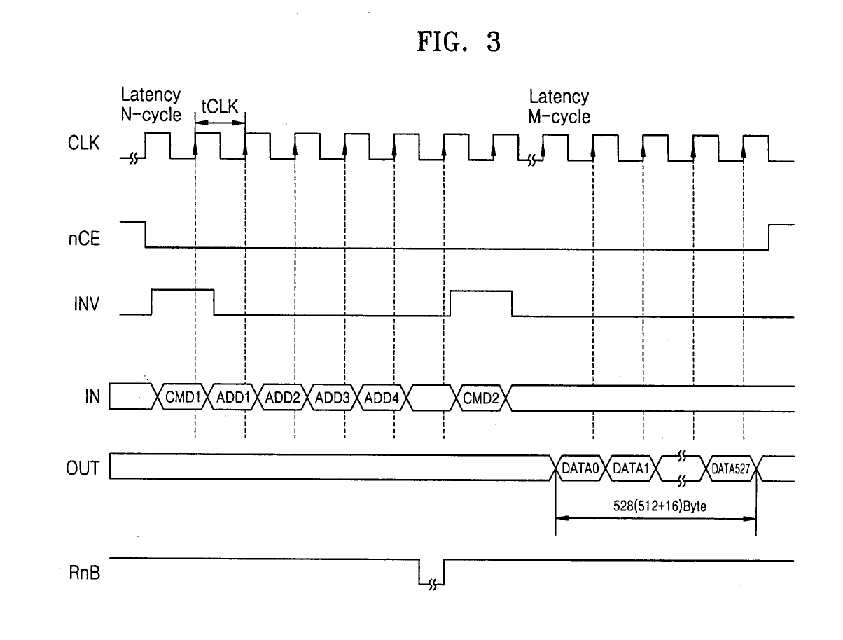

FIG. 3 is an example timing chart illustrating a read operation of the flash memory device of FIG. 1. Referring to FIG. 3, an example method for reading data from the flash memory device according to embodiments of the invention will be described in detail as follows.

A chip enable signal nCE is activated to a logic low level. A read command CMD1 and addresses ADD1 through ADD4 are received sequentially in synchronization to an external system clock CLK after a predetermined latency (N cycle) is elapsed from when the chip enable signal nCE is activated. Thus, in the state that a signal RnB is low, data is read from the flash memory cell array in the flash memory device and stored in a latch.

Then, the signal RnB is changed to a logic high level and a confirm command CMD2 is received. Read data DATA0 through DATA527 stored in the latch is output to outside the flash memory device through the data input/output (DQ) pin, in synchronization to the external system clock CLK after a predetermined latency (M cycle) is elapsed from when the confirm command CMD2 is received.

Here, the read command CMD1 and the confirm command CMD2 are received in the state that the invoke signal INV is activated. The latency (N cycle) and the latency (M cycle) can be changed as necessary.

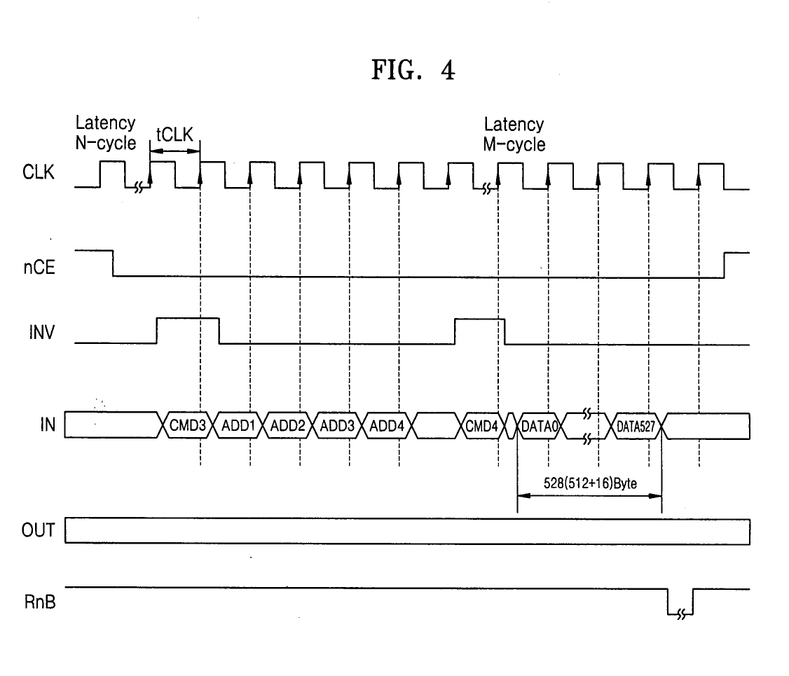

FIG. 4 is a timing chart illustrating an example program operation of the flash memory device of FIG. 1 according to embodiments of the invention. Referring to FIG. 4, a method for programming data in the flash memory device will be described in detail as follows.

A chip enable signal nCE is activated to a logic low level. A program command CMD3 and addresses ADD1 through ADD4 are received sequentially in synchronization to an external system clock CLK after a predetermined latency (N cycle) is elapsed from when the chip enable signal nCE is activated.

Then, a confirm command CMD4 is received. Program data DATA0 through DATA527 are received sequentially through a data input/output (DQ) pin from an external source in synchronization to the external system clock CLK after a predetermined latency (M cycle) is elapsed from when the confirm command CMD4 is received. Then, a signal RnB is changed to a logic low state. The program data is programmed into the flash memory cell array in the flash memory device during the state that the signal RnB is low. When the programming operation is complete, the signal RnB is changed to a logic high level to wait a next command.

The program command CMD3 and the confirm command CMD4 are received in the state that the invoke signal INV is activated. The latency (N cycle) and the latency (M cycle) can be changed as necessary.

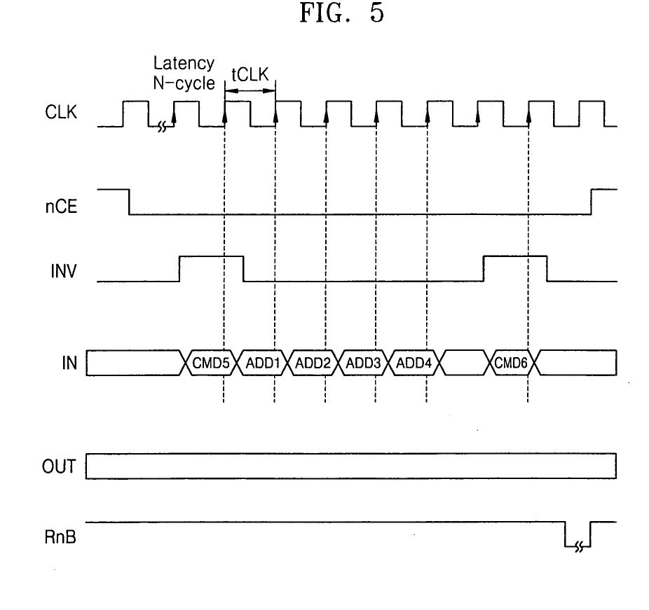

FIG. 5 is a timing chart illustrating an example erase operation of the flash memory device of FIG. 1 according to embodiments of the invention. Referring to FIG. 5, a method for erasing data stored in the flash memory device will be described in detail as follows.

A chip enable signal nCE is activated to a logic low level. An erase command CMD5 and addresses ADD1 through ADD4 are received sequentially in synchronization to an external system clock CLK after a predetermined latency (N cycle) is elapsed from when the chip enable signal nCE is activated.

Thereafter, a confirm command CMD6 is received. A signal RnB is changed to a logic low level after the confirm command CMD6 is received. In the state that the signal RnB is low, data stored in the flash memory device is erased. When the erasing operation is complete, the signal RnB is changed to a logic high level to wait a next command.

The erase command CMD5 and the confirm command CMD6 are received during the state that the invoke signal INV is activated. The latency (N cycle) can be changed as necessary.

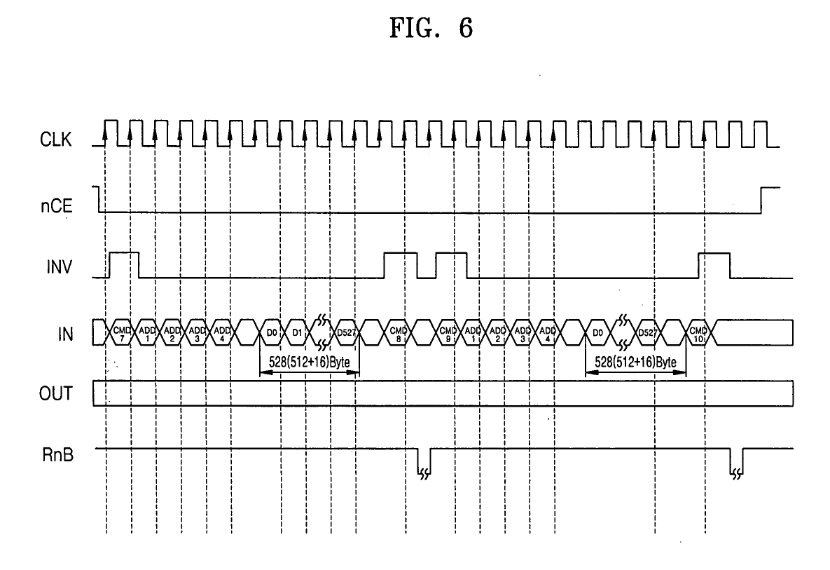

FIG. 6 is a timing chart illustrating an example cache program operation of the flash memory device of FIG. 1 according to embodiments of the invention. Referring to FIG. 6, a cache program method of the flash memory device will be described in more detail as follows.

A chip enable signal nCE is activated to a logic low level. A cache program command CMD7 and addresses ADD1 through ADD4 are received sequentially in synchronization to an external system clock CLK after a predetermined latency is elapsed from when the chip enable signal nCE is activated.

Then, a confirm command (not shown) is received. Program data D0 through D527 are received sequentially from an external source through a data input/output (DQ) pin, in synchronization to an external system clock CLK after a predetermined latency is elapsed from when the confirm command is received. Next, a signal RnB is changed to a logic low state, and the program data is programmed into the flash memory cell array inside the flash memory device during the state that the signal RnB is low.

Thereafter, the signal RnB is changed to a logic high level by a command CMD8, and then a program command CMD9 and addresses ADD1 through ADD4 are received sequentially. Thus, another set of program data D0 through D527 are received sequentially from an external source through the data input/output (DQ) pin in synchronization to the external system clock CLK after a predetermined latency is elapsed. Then, the signal RnB is again changed to a logic low level. The second set of program data is programmed into the flash memory cell array inside the flash memory device during the state that the signal RnB is low, and then the cache program operation is terminated.

Of course, the above description of embodiments of the invention can be practiced in various ways without deviating from the inventive scope of the invention. What follows are descriptions of particular, non-limiting example embodiments.

According to an embodiment of the invention, there is provided a non-volatile memory device including: a non-volatile memory cell array; and an interface circuit, which receives a command and addresses sequentially, in synchronization to an external system clock after a predetermined first latency is elapsed from when a chip enable signal is activated, in a read operation, in a program operation, and in an erase operation.

The interface circuit receives the command in response to activation of an invoke signal. The interface circuit outputs read data sequentially to the outside of the non-volatile memory device in synchronization to the external system clock after a predetermined second latency is elapsed from when a confirm command is received after the command and the addresses are received, in the read operation.

The interface circuit receives program data sequentially in synchronization to the external system clock after a predetermined second latency is elapsed from when a confirm command is received after the command and the addresses are received, in the program operation. The interface circuit receives the confirm command in response to activation of the invoke signal.

According to another embodiment of the invention, there is provided a memory system including: a memory controller; and a non-volatile memory device which is connected to the memory controller, wherein the non-volatile memory device includes, a non-volatile memory cell array, and an interface circuit, which receives a command and addresses sequentially, in synchronization to an external system clock after a predetermined first latency is elapsed from when a chip enable signal is activated, in a read operation, in a program operation and in an erase operation, wherein the memory controller provides the chip enable signal, the command, and the addresses.

The interface circuit receives the command in response to activation of an invoke signal.

The interface circuit outputs read data sequentially to an external source, in synchronization to the external system clock after a predetermined second latency is elapsed from when a confirm command is received after the command and the addresses are received, in the read operation.

The interface circuit receives program data sequentially, in response to the external system clock after a predetermined second latency is elapsed from when a confirm command is received after the command and the addresses are received, in the program operation.

The interface circuit receives the confirm command in response to activation of the invoke signal.

The memory controller provides the confirm command and the invoke signal is generated in the non-volatile memory device.

According to still another embodiment of the invention, there is provided a method for operating a non-volatile memory device including: activating a chip enable signal; and sequentially receiving a command and addresses sequentially in synchronization to an external system clock after a predetermined latency is elapsed from when the chip enable signal is activated.

The command is received in response to activation of an invoke signal.

According to another embodiment of the invention, there is provided a method for reading data from a non-volatile memory device, the method including: activating a chip enable signal; sequentially receiving a command and addresses in synchronization to an external system clock after a predetermined first latency is elapsed from when the chip enable signal is activated; receiving a confirm command after the command and the addresses are received; and outputting read data sequentially to the outside of the non-volatile memory device, in synchronization to the external system clock after a predetermined second latency is elapsed from when the confirm command is received.

The command and the confirm command are received in response to activation of an invoke signal.

According to another embodiment of the invention, there is provided a method for programming data in a non-volatile memory device, the method including: activating a chip enable signal; receiving a command and addresses sequentially in synchronization to an external system clock after a predetermined first latency is elapsed from when the chip enable signal is activated; receiving a confirm command after the command and the addresses are received; and receiving program data sequentially in synchronization to the external system clock after a predetermined second latency is elapsed from when the confirm command is received.

The command and the confirm command are received in response to activation of an invoke signal.

As described above, since the flash memory device 100 according to the present invention does not require CLE signals, ALE signals, RE signals and WE signals, internal circuits of the flash memory device 100 can be simply controlled, thereby reducing a probability of skew generation in chips, improving performance, and decreasing the number of required pins.

While the invention has been particularly shown and described with reference to exemplary embodiments thereof, it will be understood by those of ordinary skill in the art that various changes in form and details may be made therein without departing from the spirit and scope of the present invention as defined by the following claims.

1. A non-volatile memory device comprising:
a non-volatile memory cell array; and
an interface circuit, structured to receive a command and addresses sequentially, in synchronization with an external system clock after a predetermined first latency is elapsed from when a chip enable signal is activated, in a read operation, in a program operation, and in an erase operation.

2. The non-volatile memory device of claim 1, wherein the interface circuit receives the command in response to activation of an invoke signal.

3. The non-volatile memory device of claim 2, wherein, in the read operation, the interface circuit outputs read data sequentially to the outside of the non-volatile memory device in synchronization to the external system clock after a predetermined second latency is elapsed from when a confirm command is received after the command and the addresses are received.

4. The non-volatile memory device of claim 2, wherein, in the program operation, the interface circuit receives program data sequentially in synchronization to the external system clock after a predetermined second latency is elapsed from when a confirm command is received after the command and the addresses are received.

5. The non-volatile memory device of claim 3 , wherein the interface circuit receives the confirm command in response to activation of the invoke signal.

6. The non-volatile memory device of claim 1, further comprising:
a register structured to store a value of the latency and to provide the latency value to the interface circuit.

7. A memory system comprising:
a memory controller that provides a chip enable signal, a command and addresses; and
a non-volatile memory device which is connected to the memory controller, wherein the non-volatile memory device includes,
a non-volatile memory cell array, and
an interface circuit, which receives the command and the addresses sequentially, in synchronization to an external system clock after a predetermined first latency is elapsed from when the chip enable signal is activated, in a read operation, in a program operation, and in an erase operation.

8. The memory system of claim 7, wherein the interface circuit receives the command in response to activation of an invoke signal.

9. The memory system of claim 8, wherein, in the read operation, the interface circuit outputs read data sequentially to an external source, in synchronization to the external system clock after a predetermined second latency is elapsed from when a confirm command is received after the command and the addresses are received.

10. The memory system of claim 8, wherein, in the program operation, the interface circuit receives program data sequentially, in response to the external system clock after a predetermined second latency is elapsed from when a confirm command is received after the command and the addresses are received.

11. The memory system of claim 9, wherein the interface circuit receives the confirm command in response to activation of the invoke signal.

12. The memory system of claim 7, wherein the non-volatile memory device further comprises:
a register storing a value of the latency and providing the latency value to the interface circuit.

13. The memory system of claim 7, wherein the memory controller provides the invoke signal and the confirm command.

14. The memory system of claim 7, wherein the memory controller provides the confirm command and the invoke signal is generated in the non-volatile memory device.

15. A method of operating a non-volatile memory device comprising:
activating a chip enable signal; and
sequentially receiving a command and addresses sequentially in synchronization with an external system clock after a predetermined latency is elapsed from when the chip enable signal is activated.

16. The method of claim 15, wherein the command is received in response to activation of an invoke signal.

17. A method of reading data from a non-volatile memory device, the method comprising:
activating a chip enable signal;
sequentially receiving a command and addresses in synchronization with an external system clock after a predetermined first latency is elapsed from when the chip enable signal is activated;
receiving a confirm command after the command and the addresses are received; and
outputting read data sequentially to the outside of the non-volatile memory device, in synchronization with the external system clock after a predetermined second latency is elapsed from when the confirm command is received.

18. The method of claim 17, wherein the command and the confirm command are received in response to activation of an invoke signal.

19. A method of programming data in a non-volatile memory device, the method comprising:
activating a chip enable signal;
receiving a command and addresses sequentially in synchronization with an external system clock after a predetermined first latency is elapsed from when the chip enable signal is activated;
receiving a confirm command after the command and the addresses are received; and
receiving program data sequentially in synchronization with the external system clock after a predetermined second latency is elapsed from when the confirm command is received.

20. The method of claim 19, wherein the command and the confirm command are received in response to activation of an invoke signal.
